(19) United States
(12) Patent Application Publication
(10) Pub. No.: US 2024/0307998 A1
(43) Pub. Date: Sep. 19, 2024

(54) MICROSCOPE

(71) Applicant: DISCO CORPORATION, Tokyo (JP)

(72) Inventor: Takehito KAWASUMI, Tokyo (JP)

(21) Appl. No.: 18/592,745

(22) Filed: Mar. 1, 2024

(30) Foreign Application Priority Data
Mar. 14, 2023 (JP) 2023-039588

(51) Int. Cl. B23K 26/03; B23K 26/06

(52) U.S. Cl. CPC B23K 26/032; B23K 26/0648; B23K 26/0665

(57) ABSTRACT

An observation method for irradiating one side of an object, the object having a plate shape, the one side, and the other side, with a light beam, and observing the other side of the object or an interior of the object includes a holding step of holding the object at the other side on a holding surface of a holding table, and a detection step of irradiating the object with the light beam from a lighting unit capable of applying the light beam with a wavelength having transmissivity for the object, with a focal point of the light beam being positioned at a predetermined position on the other side or in the interior, and detecting reflected light from the object by an imaging unit including an objective lens having an optical axis inclined obliquely to an optical axis of a condenser lens of the lighting unit.

### BACKGROUND OF THE INVENTION

### Field of the Invention

The present invention relates to an observation method for observing, from one side of an object having a plate shape, the other side of the object located on an opposite side to the one side or an interior of the object, a microscope for realizing the observation method, and a processing machine including the microscope.

### Description of the Related Art

When dividing a workpiece such as a semiconductor wafer into a plurality of device chips, a processing machine such as a cutting machine or a laser processing machine is used. When processing such as division is applied to the workpiece using the processing machine, the workpiece is generally held at a side of its back surface under suction on a disk-shaped holding table. Here, the workpiece is upwardly exposed at its front surface.

On the front surface of the workpiece, a plurality of scribe lines (in other words, streets) is set in a grid pattern. In respective rectangular regions defined by the scribe lines, devices such as integrated circuits (ICs) and predetermined patterns (called “key patterns,” “alignment patterns,” or “alignment marks”) useful in detecting processing positions are formed.

When the workpiece is processed by the processing machine, an image with the devices and predetermined patterns included therein is acquired by imaging a side of the exposed front surface of the workpiece using a light beam having a wavelength in the visible wavelength range. The detection of the processing position is then performed on the basis of two or more of the predetermined patterns located at positions remote from each other along one of the scribe lines.

In recent years, the workpiece may be held at the side of its front surface under suction on the holding table such that its back surface is exposed upward. In this case, a light beam of a wavelength having transmissivity for the workpiece is used as an illumination light beam according to the material of the workpiece. If the workpiece has a silicon wafer, for example, it is known to perform imaging of predetermined patterns on the side of the front surface of the workpiece through the back surface by applying a light beam of an infrared light wavelength using coaxial lighting (see, for example, Japanese Patent Laid-open No. H 7-75955).

Depending on the material of the workpiece, however, the illumination light beam may be absorbed in an interior of the workpiece and may not reach its front surface. If the concentration of a dopant in a workpiece is raised to lower the electrical resistivity of devices, there is a problem that an illumination light beam irradiated from the back surface toward the front surface is absorbed in the interior of the workpiece and does not reach the front surface.

If a workpiece is observed in a similar manner to dark field microscopy using oblique lighting that irradiates parallel light beams from a plurality of respective light sources arranged along an outer peripheral potion of a lens barrel (see, for example, Japanese Utility Model Registration No. 3142994), there is also a problem that the illumination light beams irradiated from its back surface toward its front surface are absorbed in an interior of the workpiece and does not reach the front surface.

In addition, before a workpiece is divided into a plurality of device chips, the workpiece may be ground at the side of its back surface to thin the device chips. There is also a problem that an illumination light beam may be scattered by saw marks (in other words, grinding marks) formed on the side of the back surface through the grinding, thereby causing noise in an image of the side of its front surface and failing to acquire a clear image of the side of the front surface.

### SUMMARY OF THE INVENTION

With such problems in view, the present invention has as an object thereof to allow a large quantity of light to reach the side of a front surface of a workpiece compared with the conventional technique of coaxial lighting or oblique lighting when imaging the side of the front surface through a back surface of the workpiece held at the side of the front surface and exposed at the side of the back surface using an illumination light beam of a wavelength having transmissivity for the workpiece.

In accordance with a first aspect of the present invention, there is provided an observation method for irradiating one side of an object, the object having a plate shape, the one side, and the other side located on an opposite side to the one side, with a light beam, and observing the other side of the object or an interior of the object. The observation method includes a holding step of holding the object at the other side on a holding surface of a holding table, and a detection step of, after the holding step, irradiating the object with the light beam from a lighting unit that is capable of irradiating the light beam with a wavelength having transmissivity for the object, with a focal point of the light beam being positioned at a predetermined position on the other side or in the interior, and detecting reflected light from the object by an imaging unit including an objective lens having an optical axis inclined obliquely to an optical axis of a condenser lens of the lighting unit.

Preferably, in the detection step, at least one additional lighting unit that has a condenser lens having an optical axis inclined obliquely to the optical axis of the objective lens and is capable of irradiating the object with a light beam with the wavelength having transmissivity for the object may be used, the respective lighting units may be arranged at a plurality of positions different from one another along a circumference of a circle centering around the optical axis of the objective lens, the object may be irradiated with the light beams from the respective lighting units with the focal point of the light beam from the lighting unit and a focal point of the light beam from the additional lighting unit positioned at the predetermined position on the other side or in the interior, and reflected light from the object may be detected by the imaging unit.

In accordance with a second aspect of the present invention, there is provided a microscope for irradiating one side of an object, the object having a plate shape, the one side, and the other side located on an opposite side to the one side, with a light beam, and observing the other side of the object or an interior of the object. The microscope includes a lighting unit that has a light source capable of emitting the light beam with a predetermined wavelength to allow the light beam to transmit through the object, and a condenser lens capable of focusing the light beam from the light source at a predetermined position on the other side or in the interior of the object, and irradiates the object with the light beam, and an imaging unit that has an objective lens capable of allowing passage therethrough of reflected light from the object irradiated with the light beam, and an imaging sensor capable of receiving the reflected light through the objective lens. The condenser lens has an optical axis inclined obliquely to an optical axis of the objective lens.

Preferably, in a first direction from the objective lens, as a start point, on the optical axis of the objective lens to a region, as an end point, where the optical axis of the objective lens and the optical axis of the condenser lens come closest to each other, the condenser lens of the lighting unit may be arranged on a side closer to the end point than the objective lens.

Preferably, the microscope may further include at least one additional lighting unit having a light source capable of emitting a light beam with the predetermined wavelength, and a condenser lens capable of focusing the light beam from the light source at the predetermined position on the other side or in the interior of the object and having an optical axis inclined obliquely to the optical axis of the objective lens. The respective lighting units may be arranged at a plurality of positions different from one another along a circumference of a circle centering around the optical axis of the objective lens, and the optical axes of the condenser lenses in the respective lighting units are inclined obliquely to the optical axis of the objective lens.

In accordance with a third aspect of the present invention, there is provided a processing machine for processing a workpiece having a plate shape. The processing machine includes a holding table that has a holding surface capable of holding the workpiece, the workpiece having one side and the other side located on an opposite side to the one side, at the other side with the one side of the workpiece exposed, a processing unit that can apply processing to the workpiece held on the holding table, a microscope that can observe the other side of the workpiece or an interior of the workpiece, and a controller that has a memory and a processor, and is configured to control operations of the holding table, the processing unit, and the microscope. The microscope has a lighting unit that has a light source capable of emitting a light beam with a predetermined wavelength to allow the light beam to transmit through the workpiece, and a condenser lens capable of focusing the light beam from the light source at a predetermined position on the other side or in the interior of the object, and irradiates the workpiece with the light beam, and an imaging unit that has an objective lens capable of allowing passage therethrough of reflected light from the object irradiated with the light beam, and an imaging sensor capable of receiving the reflected light through the objective lens. The condenser lens has an optical axis inclined obliquely to an optical axis of the objective lens, and the controller applies the processing to the workpiece by controlling the processing unit on the basis of an image of the workpiece as captured by the microscope.

Preferably, in a first direction from the objective lens, as a start point, on the optical axis of the objective lens to a region, as an end point, where the optical axis of the objective lens and the optical axis of the condenser lens come closest to each other, the condenser lens of the lighting unit is arranged on a side closer to the end point than the objective lens in the microscope.

Preferably, the microscope may further include at least one additional lighting unit having a light source capable of emitting a light beam with the predetermined wavelength, and a condenser lens capable of focusing the light beam from the light source at the predetermined position on the other side or in the interior of the object and having an optical axis inclined obliquely to the optical axis of the objective lens. The respective lighting units may be arranged at a plurality of positions different from one another along a circumference of a circle centering around the optical axis of the objective lens, and the optical axes of the condenser lenses in the respective lighting units may be inclined obliquely to the optical axis of the objective lens.

Preferably, if predetermined patterns usable when a detection of a processing position of the workpiece is performed are formed on the other side of the workpiece, the controller may apply the processing to the workpiece by controlling the processing unit on the basis of an image of the other side of the workpiece, the image including the predetermined patterns, as captured by imaging the other side with the microscope.

Preferably, if saw marks caused by grinding processing are formed on the one side of the workpiece, the lighting units may include a plurality of first lighting units capable of applying light beams having a first component along a direction of some of the saw marks, the some saw marks being located in an imaging range of the imaging unit, and a plurality of second lighting units capable of applying light beams having a second component along a direction orthogonal to the first component as seen in plan view. The controller may reduce light quantities of the second lighting units compared with light quantities of the first lighting units by adjusting the light quantities of the first lighting units and the light quantities of the second lighting units.

Preferably, if saw marks caused by grinding processing are formed on the one side of the workpiece, the controller may create, on the basis of a plurality of first images acquired, respectively, by imaging the other surface under a plurality of different sets of lighting conditions changed through stepwise adjustments of the light quantity of the respective lighting units and each containing predetermined patterns formed on the other side of the workpiece and some of the saw marks, a plurality of second images each containing the some saw marks without the predetermined patterns, may calculate a total area of the some saw marks in each second image, and may specify the lighting conditions under which the total area of the some saw marks has become smallest.

Preferably, the processing unit may include a laser beam irradiation unit having a laser oscillator, or a cutting unit having a spindle and a cutting blade fitted on a distal end portion of the spindle.

In the case of coaxial lighting, the optical axis of the condenser lens of each lighting unit and the optical axis of the objective lens, which constitutes the imaging unit, are substantially parallel to each other. The light beam that has entered the object is therefore regularly reflected on the exposed one side, and the light quantity entering the objective lens is relatively large. In the observation method according to the first aspect of the present invention, the optical axis of the condenser lens of the lighting unit is inclined obliquely to the optical axis of the objective lens that constitutes the imaging unit. Compared with the case of coaxial lighting, it is therefore possible to reduce the light quantity reflected on the one side and entering the objective lens, and to increase the light quantity scattered on the other side or in the interior of the object and entering the objective lens.

Because effects of the reflected light from the one side can be reduced as described above, the light quantity of the reflected light from the other side or interior of the object can be relatively increased. When forming an image of the other side or interior of the object, it is therefore possible to reduce noise caused by the reflected light from the one side. Further, the use of the condenser lens in the lighting unit can provide an illumination light beam such that it is allowed to pass through the one side and to focus at substantially a single point on the other side. Compared with the oblique lighting of the related art that irradiates a parallel light beam, it is hence possible to increase the light quantity of a light beam that reaches the other side or interior of the object.

In the microscope according to the second aspect of the present invention, the optical axis of the condenser lens of the lighting unit is inclined obliquely to the optical axis of the objective lens of the imaging unit, so that the effects of reflected light from the one side can be reduced compared with the case of coaxial lighting. It is therefore possible to reduce noise caused by the reflected light from the one side. Compared with the oblique lighting of the related art that irradiates a parallel light beam, it is also possible to increase the light quantity of a light beam that reaches the other side or interior of the object.

The processing machine according to the third aspect of the present invention has the above-mentioned microscope, so that the effects of reflected light from the one side can be reduced compared with the case of coaxial lighting. It is therefore possible to reduce noise caused by the reflected light from the one side. Compared with the oblique lighting of the related art that irradiates a parallel light beam, it is also possible to increase the light quantity of a light beam that reaches the other side or interior of the workpiece.

The above and other objects, features and advantages of the present invention and the manner of realizing them will become more apparent, and the invention itself will best be understood from a study of the following description and appended claims with reference to the attached drawings showing some preferred embodiments of the invention.

### BRIEF DESCRIPTION OF THE DRAWINGS

FIG. 1A is a perspective view of a side of a front surface of an object to be observed by an observation method according to an embodiment of the first aspect of the present invention;

FIG. 1B is an enlarged plan view of a region on the side of the front surface of the object of FIG. 1A;

FIG. 2 is a fragmentary cross-sectional view of the object taken along line II-II of FIG. 1A;

FIG. 3 is an enlarged perspective view of a microscope according to an embodiment of the second aspect of the present invention;

FIG. 4A is an enlarged perspective view of a lower end section of the microscope of FIG. 3;

FIG. 4B is a partly cross-sectional side view taken along line IVB-IVB of FIG. 4A;

FIG. 5 is a schematic view depicting an inclination angle of optical axes of condenser lenses in the microscope of FIG. 3;

FIG. 6A is a schematic view depicting an example of the inclination angle of the optical axis of one of the condenser lenses of FIG. 5;

FIG. 6B is a schematic view depicting another example of the inclination angle in FIG. 5;

FIG. 7 is a flow diagram of the observation method according to the embodiment of the first aspect of the present invention;

FIG. 8A is a side view depicting a holding step of the observation method of FIG. 7;

FIG. 8B is a side view depicting a detection step of the observation method of FIG. 7;

FIG. 9 is a side view schematically depicting a laser processing machine as a processing machine according to a first embodiment of the third aspect of the present invention;

FIG. 10 is a plan view of a side of a back surface of a workpiece, which has saw marks and is to be processed by the laser processing machine of FIG. 9;

FIG. 11 is a flow diagram of a selection method of lighting conditions by the microscope of FIG. 3 included in the laser processing machine of FIG. 9;

FIG. 12A is a schematic view of a first image of a side of a front surface including saw marks, as captured under the lighting conditions selected in FIG. 11;

FIG. 12B is a schematic view of a second image with only the saw marks extracted from the first image of FIG. 12A;

FIG. 12C is a schematic view of an image (specifically, third image) of the side of the front surface, which corresponds to the lighting conditions selected in FIG. 11; and

FIG. 13 is a side view schematically depicting a cutting machine as a processing machine according to a second embodiment of the third aspect of the present invention.

### DETAILED DESCRIPTION OF THE PREFERRED EMBODIMENT

### (Observation Method and Microscope)

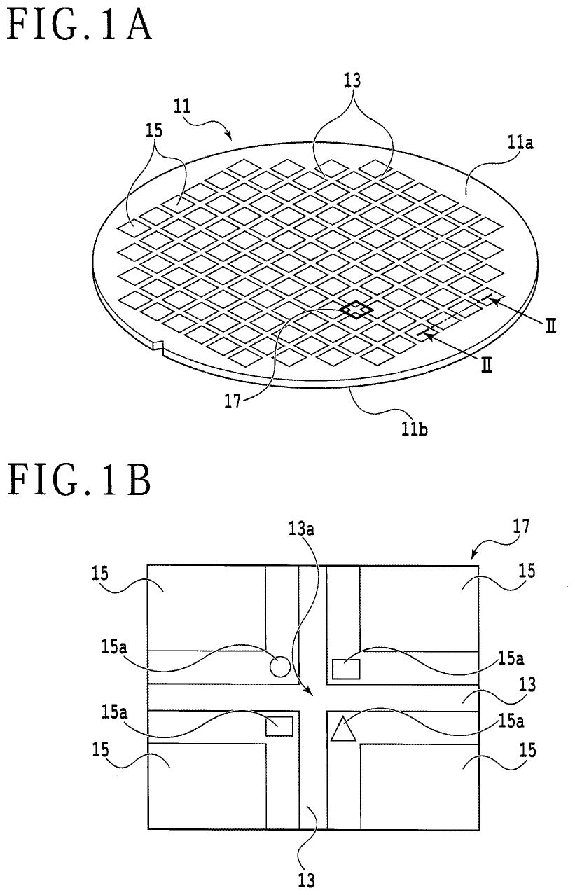

With reference to FIGS. 1A through 8B, an observation method according to an embodiment of the first aspect of the present invention and a microscope 2 according to an embodiment of the second aspect of the present invention will be first described. FIG. 1A is a perspective view of a side of a front surface (the other side) 11a of an object 11. The object 11 has a disk-shaped (in other words, has a plate shape) silicon single crystal substrate (in other words, silicon wafer) having a thickness of approximately 50 μm to 800 μm.

The silicon wafer in this embodiment contains a relatively high concentration of a dopant. The silicon wafer therefore has a resistivity of, for example, 0.001 Ω·cm or higher and 0.1 Ω·cm or lower. It is to be noted that no limitations are imposed on the material, shape, structure, size, and the like of the object 11. The object 11 may have a single crystal substrate of another semiconductor material such as gallium nitride (GaN), silicon carbide (SiC), diamond, or gallium oxide (Ga₂O₃)—instead of silicon (Si).

On the side of the front surface 11a of the object 11, a stacked structure is formed in which metal layers and interlayer dielectrics (low-k films) are alternately stacked. On the front surface 11a, a plurality of scribe lines (streets) 13 is formed in a grid pattern to serve as cutting regions.

The scribe lines 13 may be formed by small ruggedness of a stacked structure of metal layers and interlayer dielectrics or may also be formed in a fashion substantially free of ruggedness by drawing them with an electron beam lithography exposure (not depicted). In respective rectangular regions defined by the scribe lines 13, devices 15 such as ICs are formed. No limitations are however imposed on the kind, number, shape, construction, size, arrangement, and the like of the devices.

FIG. 1B is an enlarged plan view of a region 17 on the side of the front surface 11a. The region 17 is located in a vicinity of an intersection 13a of two scribe lines 13 which are orthogonal to each other and contains four devices 15. At corner portions of the devices 15, the corner portions being near the intersection 13a, predetermined patterns 15a, which are usable when a detection of processing positions is performed by a processing machine such as a laser processing machine 32 or a cutting machine 52, are formed, respectively, in a fashion that they are exposed at the front surface 11a.

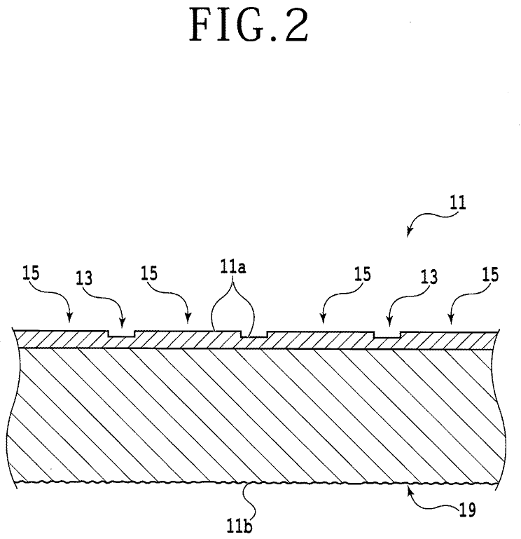

FIG. 2 is a fragmentary cross-sectional view of the object 11 taken along line II-II of FIG. 1A. On a side of a back surface (one surface) 11b of the object 11 located on an opposite side to the front surface 11a, an irregular area 19 is exposed. It is to be noted that the irregularity of the irregular area 19 is exaggerated in FIG. 2. The irregular area 19 has been formed in association with thinning of the silicon wafer by applying infeed grinding to the side of the back surface 11b.

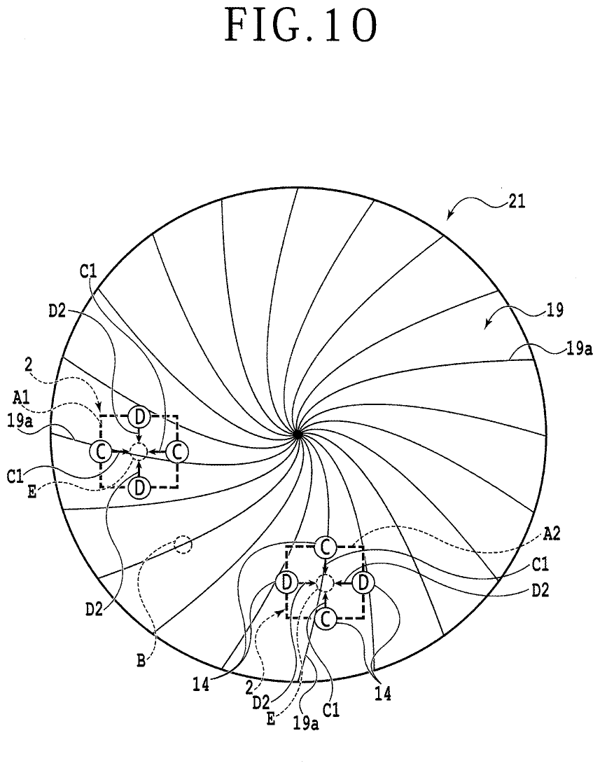

In the infeed grinding, with the silicon wafer and an annular grinding wheel (not depicted) both kept rotating, the silicon wafer is ground using a region of an approximately ¼ circumference of the grinding wheel. The irregular area 19 includes a plurality of saw marks (in other words, grinding marks) 19a (see FIG. 10). As depicted in FIG. 10, each saw mark 19a is a circular arc curve, and the saw marks 19a are radially arranged as seen in plan view.

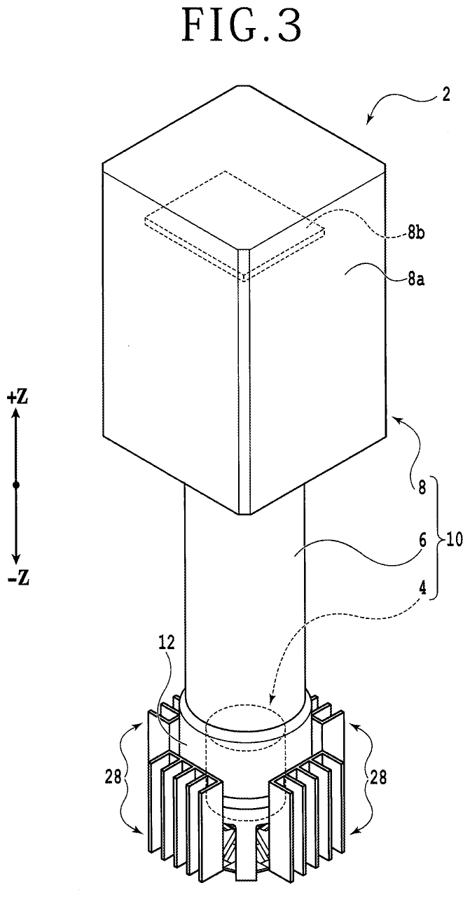

Referring to FIGS. 3 to 7B, a description will next be made about the microscope 2 of this embodiment for observing the side of the front surface 11a of the object 11 through the back surface 11b. FIG. 3 is an enlarged perspective view of the microscope 2. A Z-axis direction indicated in FIG. 3 is substantially parallel to a height direction of the microscope 2, and is parallel, for example, to a vertical direction. The Z-axis direction is also parallel to a +Z direction (in other words, an upward direction) and a −Z direction (in other words, a downward direction) extending in opposite directions to each other.

The microscope 2 of this embodiment is used to observe the front surface 11a of the object 11 or an interior of the object 11 by irradiating the back surface 11b of the object 11 with a light beam having a wavelength (for example, a wavelength of 1,000 nm or longer and 1,700 nm or shorter) in the near infrared range. As depicted in FIG. 3, the microscope 2 has an objective lens 4.

The objective lens 4 has a specification including a lens and a lens barrel and specialized for observation of the object 11 using a light beam of the wavelength in the near infrared range. Reflected light from the object 11 passes through the objective lens 4, and the reflected light beam traveled through the objective lens 4 passes through a cylindrical lens barrel 6 and impinges on a near infrared camera 8. The near infrared camera 8 has a rectangular parallelepipedal housing 8a.

In the housing 8a, an image sensor 8b such as a complementary metal-oxide semiconductor (CMOS) image sensor or a charge-coupled device (CCD) image sensor is arranged. The image sensor 8b is, for example, an area sensor that can image a two-dimensional area. The image sensor 8b has a plurality of photodiodes (not depicted) that can subject an infrared light beam to photoelectric conversion. Each photodiode includes a photoelectric conversion region formed, for example, of indium gallium arsenide (InGaAs).

The image sensor 8b receives the reflected light having passed through the objective lens 4 and lens barrel 6. The objective lens 4, the lens barrel 6, the near infrared camera 8, and the like constitute an imaging unit 10 that receives the reflected light from the object 11. To a lower end portion of the lens barrel 6, a cylindrical bracket 12 is disposed so as to surround a circumference of the objective lens 4.

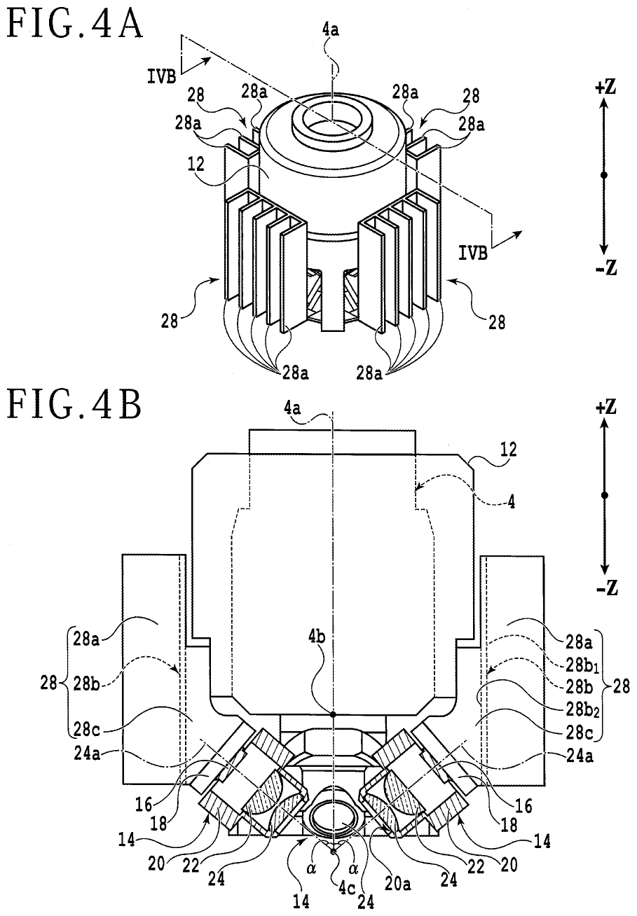

With reference to FIGS. 4A and 4B, a description will next be made about a construction in a vicinity of the bracket 12. FIG. 4A is an enlarged perspective view of a lower end section of the microscope 2, and FIG. 4B is a partly cross-sectional side view taken along line IVB-IVB of FIG. 4A. The microscope 2 of this embodiment has four (a plurality of) lighting units 14 arranged around the bracket 12. The four lighting units 14 are arranged at a plurality of positions different from one another along a circumference of a circle centering around an optical axis 4a of the objective lens 4 (specifically, an optical axis of one or more lenses that make up the objective lens 4) arranged substantially parallel to the Z-axis direction.

Each lighting unit 14 has a light source 16 such as a light emitting diode (LED). The light source 16 is a high luminance LED that emits a light beam having a predetermined wavelength (for example, a near infrared light beam of a central wavelength of 1,200 nm) determined beforehand such that the light beam transmits through the object 11. It is to be noted that, in this embodiment, the light quantity of the light beam from the light source 16 can be adjusted stepwise from level 1 (light quantity: zero) to level 5 (light quantity: maximum), although the light quantity may be adjustable to a plurality of levels more than five levels, or the light quantity may be continuously adjustable.

In this embodiment, with the object 11 irradiated with the light beams from the light sources 16 in a direction from the back surface 11b toward the front surface 11a, the front surface 11a or the interior of the silicon wafer is observed in such a manner that the light beams transmit through the silicon wafer. Near infrared light beams capable of transmitting through the silicon wafer are used accordingly. Nonetheless, the wavelength to be used is not limited to that of near infrared light. If the object 11 has a SiC wafer, for example, light beams having a wavelength of visible light in a range of 360 nm or longer and 830 nm or shorter are irradiated from the light sources 16 instead of infrared light beams. As described above, the wavelength of the light sources 16 is appropriately selected according to the wafer that constitutes the object 11. According to the wavelength of the light beams to be emitted from the light sources 16, a plurality of photodiodes that can subject the light beams of the wavelength to photoelectric conversion is also adopted in the image sensor 8b.

Each light source 16 is fixed on one side of a disk-shaped base plate 18. On the one side of the disk-shaped base plate 18, a cylindrical casing 20 is fixed such that the casing 20 covers the light source 16. In the casing 20, a plano-convex collimate lens 22 is fixed. In the casing 20, a plano-convex condenser lens 24 is fixed on an opposite side to the light source 16 with respect to the collimate lens 22. An optical axis of the collimate lens 22 and an optical axis 24a of the condenser lens 24 are arranged such that they substantially coincide with each other.

With the light beam emitted from each light source 16, the object 11 is irradiated from an opening 20a of the casing 20 by way of the collimate lens 22 and the condenser lens 24. The irradiated light beam is then focused at a predetermined position set in a vicinity of an intersection 4c of the optical axis 4a of the objective lens 4 and the optical axis 24a of the condenser lens 24. This predetermined position is on the front surface 11a or in the interior of the object 11.

In this embodiment, the use of the condenser lens 24 in each lighting unit 14 can provide an illumination light beam such that it is allowed to pass through the back surface 11b toward the side of the front surface 11a and to focus at substantially a single point. Compared with the oblique lighting of the related art that irradiates a parallel light beam, it is hence possible to increase the light quantity of the light beam that reaches the front surface 11a or interior of the object 11.

In addition, the focusing of the light beams from the respective lighting units 14 at the same predetermined position on or in the object 11 can provide a large light quantity at the substantially single point on or in the object 11 compared with the case of use of a single lighting unit 14 alone. Even in the case where the object 11 has a silicon wafer containing a relatively high concentration of a dopant, the object can be irradiated at the predetermined position with a large light quantity of light beams compared with the case of the use of the single lighting unit 14 alone. Further, a clear image can be obtained as a light quantity sufficient for imaging reaches the side of the front surface 11a.

It is to be noted that the above-mentioned intersection 4c is an example of a region where the optical axis 4a and the optical axis 24a come closest to each other. The optical axis 4a and the optical axis 24a are not absolutely required to intersect with each other at a single point. Even if the optical axis 4a and the optical axis 24a are slightly apart from each other and are in a twisted positional relation, for example, the light beam from each light source 16 is focused by the condenser lens 24 in the region where the optical axis 4a and the optical axis 24a come closest to each other. Each condenser lens 24 is arranged lower than a lower end 4b of the objective lens 4 (in other words, on a side of the intersection 4c) in the −Z direction (in other words, a first direction). It is to be noted that the −Z direction corresponds to a direction from the lower end 4b, as a start point, of the objective lens 4 on the optical axis 4a of the objective lens 4 to the intersection 4c, as an end point, of the optical axis 4a of the objective lens 4 and the optical axis 24a of the condenser lens 24.

Now, to irradiate the object 11 with more light, it is preferred to make greater the numerical aperture (NA) of each condenser lens 24. Numerical aperture is proportional to lens diameter. If the diameter of the condenser lens 24 is increased, however, a problem arises in that the condenser lens 24 and the objective lens 4 physically interfere with each other.

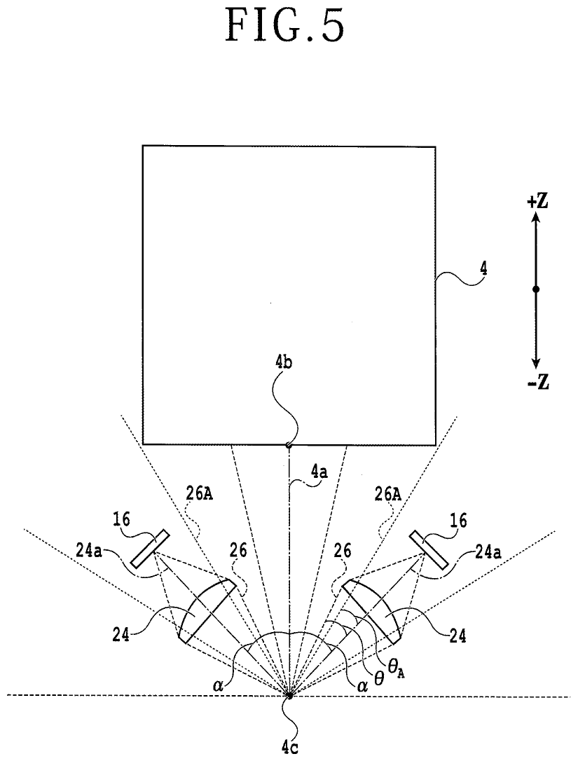

In contrast, each condenser lens 24 is arranged at a position very close to the object 11 below the objective lens 4 in this embodiment, so that a condenser lens having a short focal distance (FD) can be adopted as the condenser lens 24. By making the focal distance shorter, an angular aperture θ (see FIG. 5) can be made relatively large even if the lens dimeter of the condenser lens 24 is relatively small. As described above, a relatively large numerical aperture can be realized even if the lens diameter of the condenser lens 24 is relatively small. A suppression of the interference between the condenser lens 24 and the objective lens 4 and the use of a condenser lens of a relatively large numerical aperture as the condenser lens 24 can be both realized accordingly.

As a comparative example, it may be conceivable to realize substantially the same numerical aperture as that of each condenser lens 24 depicted in FIG. 4B by using a condenser lens (not depicted) of a large focal distance and lens diameter with the condenser lens arranged above the lower end 4b in a side way of the objective lens 4. This however increases the size and weight of the microscope 2. For the realization of the microscope 2 with a small size and lightweight, it is therefore advantageous to arrange the condenser lenses 24, which are small in both the focal distance and the lens diameter, between the objective lens 4 and the object 11 as depicted in FIG. 4B.

As depicted in FIG. 4B, the optical axis 24a of each condenser lens 24 is inclined obliquely to the optical axis 4a of the objective lens 4 (in other words, the optical axis 4a of the objective lens 4 is inclined obliquely to the optical axis 24a of each condenser lens 24). The optical axis 4a of the objective lens 4 and the optical axis 24a of each condenser lens 24 form an inclination angle α, which is preferably 20° or greater and 80° or smaller. FIG. 5 is a simplified version of FIG. 4B and is a schematic view depicting the inclination angle α of the optical axis 24a of each condenser lens 24 with respect to the optical axis 4a of the objective lens 4.

It is to be noted that, in FIG. 5, sets of the lighting unit 14 and the light source 16, which are arranged in a pair in a left-to-right direction on the sheet of FIG. 4B, and the objective lens 4 are depicted, and the casings 20, collimate lenses 22, and the like are omitted for convenience of description. Further, the front surface 11a of the object 11 is simplified and indicated by a broken line. Furthermore, an incident light beam 26 formed by each condenser lens 24 of the angular aperture θ in this embodiment and an incident light beam 26A formed by each condenser lens (not depicted) of an angular aperture OA in the comparative example are also indicated for convenience of description in FIG. 5. As depicted in FIG. 5, this embodiment can realize both a suppression of the interference between the condenser lenses 24 and the objective lens 4 and the use of condenser lenses of the relatively large numerical aperture as the condenser lenses 24, and can also realize the microscope 2 with the small size and lightweight.

In the case of coaxial lighting (not depicted), on the other hand, a condenser lens is shared as an objective lens, so that the optical axis of the condenser lens and that of the objective lens are parallel to each other. When an illumination light beam is irradiated in a direction from the back surface 11b toward the front surface 11a using coaxial lighting, the illumination light beam is regularly reflected, and therefore the quantity of light allowed to enter the objective lens 4 is relatively large. Compared with the case of coaxial lighting, however, the light quantity of light beams to be reflected as reflected light on the side of the back surface 11b can be reduced by obliquely inclining the optical axis 24a of each condenser lens 24 to the optical axis 4a of the objective lens 4 as in this embodiment, so that the light quantity of light beams to be transmitted to the front surface 11a or interior of the object 11 can be relatively increased.

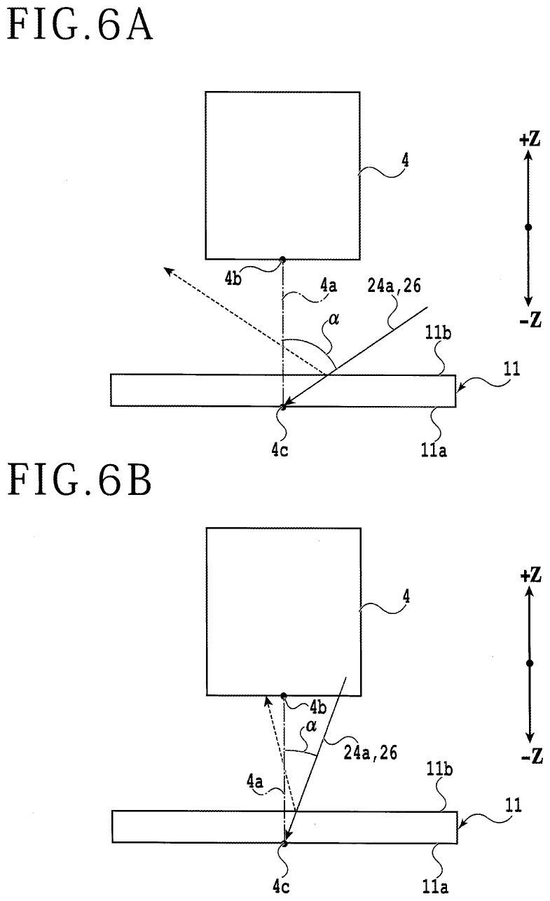

In FIGS. 6A and 6B, FIG. 5 is simplified further, and one of the lighting units 14 and the objective lens 4 are depicted. Referring to FIGS. 6A and 6B, a description will be made about a relation between the inclination angle α and reflected light reflected from the object 11 and allowed to enter the objective lens 4. The microscope 2 of this embodiment is what is called a dark field microscope, and an oblique light beam incident obliquely to the optical axis 4a of the objective lens 4 is irradiated from the back surface 11b toward the front surface 11a, and reflected light from the front surface 11a or interior of the object 11 is allowed to enter the objective lens 4. It is to be noted that the term “reflected light” as used herein is not limited only to reflected light forming, with boundary plane normal to the back surface 11b, the same angle as an angle formed by the boundary plane and an incident light beam at the incident surface (in other words, regular reflection light or specular reflection light), but includes diffuse reflection light from the object 11 caused by the incident light beam.

FIG. 6A is a schematic view depicting an example of the inclination angle α. If the inclination angle α is relatively large (for example, 20° or greater), a portion of the incident light beam 26 with which the object 11 is irradiated so as to allow it to focus in a vicinity of the front surface 11a is reflected on the back surface 11b. However, the inclination angle α is relatively large, so that the reflected light is hardly allowed to enter the objective lens 4. The diffuse reflection light beam from the front surface 11a or interior of the object 11 is hence allowed to primarily enter the objective lens 4, thereby enabling to reduce the effects of profiles of the side of the back surface 11b such as saw marks 19a formed on the side of the back surface 11b through grinding processing.

FIG. 6B is a schematic view depicting another example of the inclination angle α. If the inclination angle α is relatively small (for example, smaller than 20°), a light beam of a relatively high intensity reflected on the back surface 11b is readily allowed to enter the objective lens 4. Reflected light from the front surface 11a or interior of the object 11 is hence relatively attenuated under the effects of profiles on the side of the back surface 11b. In the example depicted in FIG. 6B, the quality of an image is higher compared with that available from coaxial lighting, but is lower compared with that available in the example depicted in FIG. 6A in which the inclination angle α is relatively large.

If the oblique lighting of the related art is used, an irradiated area by the illumination light beam with which the front surface 11a of the object 11 is irradiated increases as the inclination angle α of the optical axis 24a is made greater, and hence there is a problem that the light quantity per unit area is reduced. Especially if the attenuation of a light quantity is prone to occur in the course of transmission of an illumination light beam through the object 11 like an object that includes a silicon wafer containing a relatively high concentration of a dopant, no clear image of the side of the front surface 11a is acquired if the light quantity per unit area is reduced.

In this embodiment, in contrast, the condenser lenses 24 are adopted in the lighting units 14, and the illumination light beams are focused at substantially the single point. Even if the inclination angle α of each optical axis 24a is made greater, the irradiated area by the illumination light beam with which the front surface 11a is irradiated can hence be maintained substantially constant, so that the reduction of the light quantity per unit area can be suppressed. Compared with the use of the oblique lighting of the related art, a clearer image of the front surface 11a or interior of the object 11 can be acquired accordingly.

Referring back to FIGS. 4A and 4B, a description will now be made about heat dissipation systems 28 for the lighting units 14. Each heat dissipation system 28 has a plurality (five in the example of FIG. 4A) of fins 28a of a rectangular plate shape. Each fin 28a has a longitudinal portion arranged along the Z-axis direction. Each fin 28a is fixed at one side surface thereof on one side 28b1 of a base plate 28b. Further, the fins 28a are arranged at equal intervals in a lateral width direction of the base plate 28b.

In each base plate 28b, a bracket 28c is fixed on the other side 28b2 located on an opposite side to the one side 28b1. The bracket 28c is connected to an opposite side of the base plate 18, which fixedly secures the light source 16, to the side on which the light source 16 is arranged. The fins 28a, the base plate 28b, and the bracket 28c are formed of a metal having a relatively high thermal conductivity.

Heat generated at each light source 16 is conducted to the fins 28a by way of the bracket 28c and base plate 28b. A temperature gradient is therefore formed between the fins 28a and a region right below the fins 28a. In gaps between the adjacent fins 28a, thermal convection that proceeds in the +Z direction occurs for the thermal convection. As a consequence, the light source 16 can be cooled by the naturally occurring thermal convection without needing to form forced convection by a fan or the like. It is to be noted that thermal radiation from the base plate 28b and the bracket 28c also contributes to the cooling of the light source 16.

Through each light source 16, a relatively high current flows, so that the light source 16 generates heat during emission of a light beam. By cooling the light source 16 using the heat dissipation system 28, the extent of reduction in the luminous efficacy of the light source 16 can be reduced, and in addition, the extent of thermal effects (for example, displacements and deterioration of the light source 16, and deviations or the like of the optical axis 24a by thermal expansion of the casing 20 and the like) that occur on the microscope 2 can be also reduced.

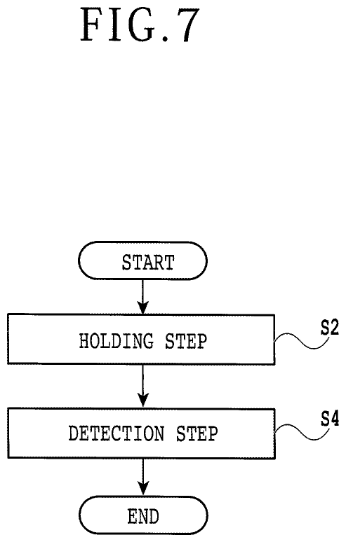

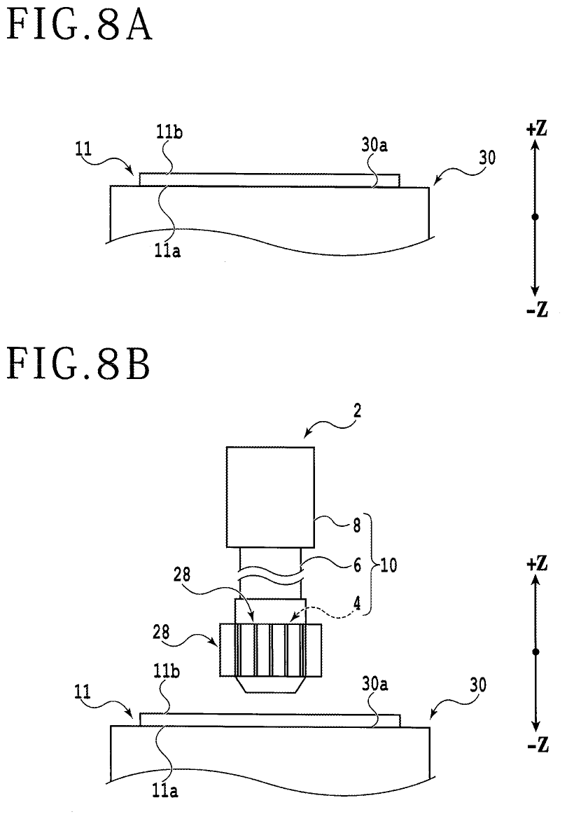

FIG. 7 is a flow diagram of the observation method of this embodiment for observing the front surface 11a or interior of the object 11 from the side of the back surface 11b using the microscope 2 of this embodiment. The observation method includes a holding step S2 of holding the object 11, and a detection step S4 of detecting reflected light from the object 11 by the imaging unit 10. FIG. 8A is a side view depicting the holding step S2. In the holding step S2, the object 11 is held at the side of the front surface 11a under suction on a holding surface 30a of a disk-shaped holding table (in other words, chuck table) 30.

The holding table 30 has a disk-shaped frame body made of a metal. On a side of an upper surface of the frame body, a disk-shaped recessed portion of a diameter smaller than the frame body is formed, and a disk-shaped porous plate formed of a porous ceramic material is fixed in the recessed portion. The upper surface of the frame body and an upper surface of the porous plate are substantially flush with each other, thereby forming the holding surface 30a as a substantially planar surface. In the frame body, predetermined flow paths are formed. To these flow paths, a suction source (not depicted) such as a vacuum pump is connected. When a negative pressure from the suction source is transmitted to the porous plate, the negative pressure is produced at the upper surface of the porous plate.

In the holding step S2 in this embodiment, the object 11 is held under suction on the holding surface 30a such that the front surface 11a comes into contact with the holding surface 30a. With a resin-made protective tape (not depicted) bonded beforehand to the side of the front surface 11a, the side of the front surface 11a may be held under suction on the holding surface 30a via the protective tape. After the holding step S2, the detection step S4 is performed using the above-mentioned microscope 2.

FIG. 8B is a side view depicting the detection step S4. In the detection step S4, with the focal points of light beams, which have a wavelength having transmissivity for the object 11, positioned at the predetermined position on the front surface 11a or in the interior of the object 11, the object 11 is irradiated with the light beams from the lighting units 14, and reflected light from the object 11 are detected by the imaging unit 10.

In particular, the optical axis 4a of the objective lens 4 is arranged such that it substantially intersects the holding surface 30a at a right angle, and the optical axis 24a of each condenser lens 24 is inclined by the inclination angle α with respect to the optical axis 4a of the objective lens 4. Compared with the case of coaxial lighting, it is therefore possible to reduce the light quantity of light reflected on the side of the back surface 11b and entering the objective lens 4, and to increase the light quantity of light scattered on the front surface 11a or in the interior of the object 11 and entering the objective lens 4.

As the effects of the reflected light from the side of the back surface 11b can be reduced as described above, the light quantity of the reflected light from the front surface 11a or interior of the object 11 can be relatively increased. When forming an image of the front surface 11a or interior of the object 11, it is therefore possible to reduce noise caused by the reflected light from the side of the back surface 11b.

Further, the use of the condenser lenses 24 in the lighting units 14 can provide illumination light beams such that they are allowed to pass through the back surface 11b toward the side of the front surface 11a and to focus at substantially the single point. Compared with the oblique lighting of the related art that irradiates parallel light beams, it is hence possible to increase the quantity of light beams that reach the front surface 11a or interior of the object 11.

As known well, it becomes exponentially difficult to image the front surface 11a or the interior through the back surface 11b as the thickness of the object 11 increases. By focusing illumination light beams at substantially a single point with the lighting units 14, the front surface 11a or interior of the object 11 can however be appropriately imaged even if the silicon wafer, which constitutes the object 11, is relatively thick.

For example, the use of the microscope 2 of this embodiment can appropriately image the front surface 11a or interior even if the silicon wafer, which constitutes the object 11, has a thickness of 100 μm or greater and 800 μm or smaller. The microscope 2 of this embodiment is more effective as the silicon wafer, which constitutes the object 11, is thicker. The silicon wafer may have a thickness of 200 μm or greater and 800 μm or smaller, may also have a thickness of 300 μm or greater and 800 μm or smaller.

### (Laser Processing Machine)

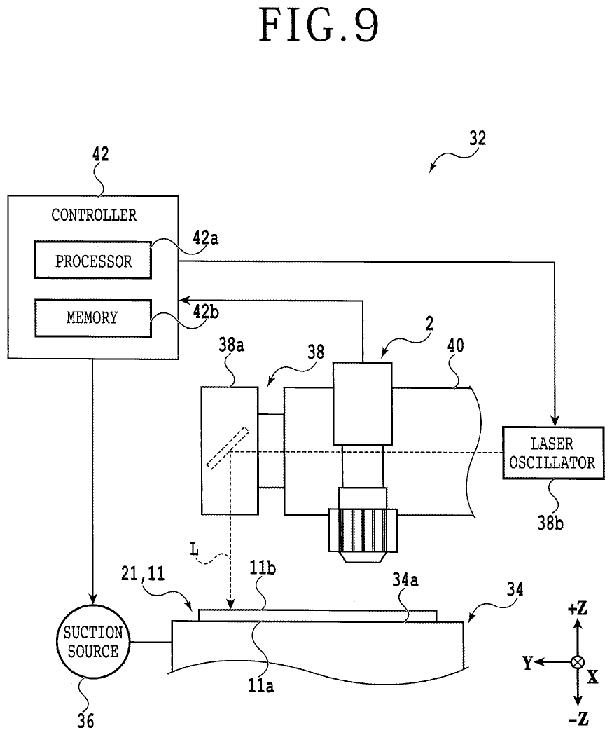

As a processing machine according to a first embodiment of the third aspect of the present invention, a laser processing machine 32 with the microscope 2 mounted thereon will next be described with reference to FIGS. 9 to 12. FIG. 9 is a side view schematically depicting the laser processing machine 32. It is to be noted that, in FIG. 9, some elements of the laser processing machine 32 are illustrated as functional blocks. With the laser processing machine 32, the above-mentioned object 11 is subjected as a workpiece 21 to laser processing.

The laser processing machine 32 has a disk-shaped holding table 34. As the holding table 34 has the same construction as that of the above-mentioned holding table 30, its detailed description is omitted. A suction source 36 such as a vacuum pump is connected to the holding table 34, and the holding table 34 holds, on a holding surface 34a thereof, the workpiece 21 under suction at the side of the front surface 11a with the side of the back surface 11b exposed. It is to be noted that the workpiece 21 may also be held under suction on the holding surface 34a via a protective tape as mentioned above.

The holding table 34 is constructed to be movable in an X-Y plane direction by a Y-axis direction moving mechanism and X-axis direction moving mechanism (both not depicted), which are each of a ball screw type. The holding table 34 is also constructed to be rotatable about a predetermined axis of rotation that is substantially parallel to a Z-axis direction. Above the holding surface 34a, an irradiation head 38a of a laser beam irradiation unit (processing unit) 38 is disposed. The irradiation head 38a irradiates a pulsed laser beam L, which has been emitted from a laser oscillator 38b, in a −Z direction.

The laser beam L has a wavelength having transmissivity for the workpiece 21 (in the case of the silicon wafer, 1,064 nm, for example). As the laser beam L has the wavelength having transmissivity for the workpiece 21, modified regions and cracks are formed in the interior of the workpiece 21 by irradiating the workpiece 21 with the laser beam L. The modifies regions are reduced in mechanical strength, and the cracks extend from the modified regions as start points. It is to be noted that the laser beam L may be applied to the workpiece 21 after conversion to a wavelength (in the case of the silicon wafer, 355 nm, for example) absorbable in the workpiece 21. If the laser beam L has the wavelength absorbable in the workpiece 21, ablation processing is applied to the workpiece 21.

The irradiation head 38a is fixed on a distal end portion of a cylindrical housing 40. The housing 40 has a longitudinal portion arranged along a Y-axis direction. In a side way of the housing 40, the above-mentioned microscope 2 is fixed via an undepicted arm extending in an X-axis direction. The microscope 2 is arranged such that the optical axis 4a of the objective lens 4 extends along the Z-axis direction. The housing 40 is constructed to be movable along the Z-axis direction by a Z-axis direction moving mechanism (not depicted) of a ball screw type. For example, the position of a focal point of the laser beam L and the focal point of the objective lens 4 of the microscope 2 are adjusted by the Z-axis direction moving mechanism.

Operations of (i) the microscope 2, (ii) the suction source 36, the X-axis direction moving mechanism, the Y-axis direction moving mechanism, and so on, all associated with the holding table 34, (iii) the laser beam irradiation unit 38, (iv) the Z-axis direction moving mechanism, and the like are controlled by a controller 42. The controller 42 is constituted by a computer, which includes, for example, a processor 42a typified by a central processing unit (CPU), and a memory 42b.

The memory 42b has a main storage device such as a dynamic random access memory (DRAM), and an auxiliary storage device such as a flash memory, a hard-disk drive, or a solid-state drive. In the auxiliary storage device, software including predetermined programs is stored. Functions of the controller 42 are realized by operating the processor 42a and the like in accordance with the software.

In the auxiliary storage device, a first program for performing a below-mentioned FFT step S30 is also stored. The processor 42a executes the first program to perform a fast Fourier transform (FFT) on a below-mentioned first image 23. In the auxiliary storage device, a second program for performing a below-mentioned extraction and calculation step S40 is also stored. The second program includes a program that applies masking processing, a program that applies an inverse Fourier transform, a program that performs black and white binarization processing on a below-mentioned second image 25 using a predetermined pixel value as a threshold, a program that counts a total pixel number of the saw marks 19a, and so on.

In addition, a third program for changing lighting conditions in a below-described light quantity change step S60, a fourth program for comparing total pixel numbers of the saw mark 19a as counted in a below-mentioned comparison step S70, and a fifth program for specifying, in a below-mentioned specification step S80, a combination of light quantities at which the total pixel number of the saw marks 19a has become smallest are also stored in the auxiliary storage device.

The controller 42 controls the laser beam irradiation unit 38 on the basis of an image of the workpiece 21 captured by the microscope 2, whereby the workpiece 21 is irradiated with the laser beam L along the scribe lines 13 (in other words, processing is applied to the workpiece 21). Described specifically, the laser processing machine 32 first specifies the scribe lines 13 by imaging the side of the front surface 11a with the microscope 2 with the side of the front surface 11a held under suction on the holding surface 34a such that the back surface 11b is exposed. However, the irregular area 19 including the saw marks 19a is formed on the side of the back surface 11b as mentioned above.

FIG. 10 is a plan view of the side of the back surface 11b of the workpiece 21, the back surface 11b having the saw marks 19a. FIG. 10 depicts, as an example, how the saw marks 19a are seen when the side of the back surface 11b of the workpiece 21 is seen in plan view. In practice, a plurality of saw marks (not depicted) of the same shape as the respective saw marks 19a is formed between each two adjacent saw marks 19a. It is to be noted that, in FIG. 10, positions of the microscope 2 are each indicated by a broken-line square and positions of the lighting units 14 are each indicated by a solid-line circle.

A position A1 of the microscope 2 as depicted in FIG. 10 indicates a relative position to the workpiece 21 at a given time and is at a location different from a position A2 of the microscope 2 at a different time. The microscope 2 can be moved from the position A1 to the position A2, for example, by rotating the holding table 34. To observe a region B located between the position A1 and the position A2 in a circumferential direction of the workpiece 21, the holding table 34 is therefore rotated such that the microscope 2 is positioned above the region B.

In each broken-line square that indicates the position of the microscope 2, the four solid-line circles schematically indicate the positions of the lighting units 14, respectively. The four lighting units 14 includes two lighting units 14 (specifically, first lighting units) located at opposing positions C as seen in plan view, and the remaining two lighting units 14 (specifically, second lighting units) located at opposing positions D as seen in plan view.

The lighting units 14 located in a pair at the positions C irradiate an imaging region E of the microscope 2 with light beams, each of which has a first component C1 along an associated saw mark 19a as seen in plan view of the workpiece 21, in addition to a component orthogonal to the back surface 11b of the workpiece 21. On the other hand, the lighting units 14 located in a pair at the positions D irradiate the imaging region E of the microscope 2 with light beams, each of which has a second component D2 orthogonal to the first component C1 as seen in plan view of the workpiece 21, in addition to a component orthogonal to the back surface 11b of the workpiece 21.

As the light beams irradiated from the lighting units 14, which are located at the positions C, toward the side of the back surface 11b have the first components C1 along the direction of the associated saw mark 19a in the imaging region E, the light quantity of light reflected on the side of the back surface 11b is smaller than that of the light irradiated from the lighting units 14, which are located at the positions D, toward the side of the back surface 11b. On the other hand, the light beams irradiated from the lighting units 14, which are located at the positions D, toward the side the back surface 11b have the second components D2 substantially orthogonal to the direction of the associated saw mark 19a in the imaging region E, and therefore are prone to be reflected on the side of the back surface 11b compared with the light beams irradiated from the lighting units 14, which are located at the positions C, toward the side of the back surface 11b. In particular, the light quantity of diffuse-reflected light is large.

To suppress the reflected light, which have been reflected on the back surface 11b, from being allowed to enter the objective lens 4, it is preferred to change the lighting conditions according to positional relations between the lighting units 14 and the associated saw mark 19a, and to image the side of the front surface 11a under optimal conditions. If the positional relations between the lighting units 14 and the associated saw mark 19a are known beforehand, the controller 42 adjusts the light quantity of each lighting unit 14, and makes the light quantity of the light beams from the lighting units 14 (the positions D), each having the second component D2, smaller than the light quantity of the light beams from the lighting units 14, each having the component C1 (the positions C).

By way of example, the light quantity of the lighting unit 14 at each position D is preferably set to level 1 (light quantity: zero). In this case, the light quantity of the lighting unit 14 at each position C is appropriately adjusted in a range of level 2 to level 5. The light quantity of each lighting unit 14 is adjusted such that, for example, neither blown-out highlights nor blocked-out shadows are formed in a resulting image. For the suppression of blown-out highlights and blocked-out shadows, the light quantity of the lighting unit 14 at each position C may be adjusted such that the average of the distribution of luminances (minimum: 0, maximum: 255) of the resulting image falls in a range of 128±60.

The selection of such lighting conditions can reduce, in an image to be acquired by imaging the side of the front surface 11a, a total area of saw marks 19a reflected in the image by reflected light from the side of the back surface 11b. If the positional relations between the lighting units 14 and the associated saw mark 19a are not known beforehand, on the other hand, the controller 42 looks for optimal lighting conditions while changing the light quantity of each lighting unit 14.

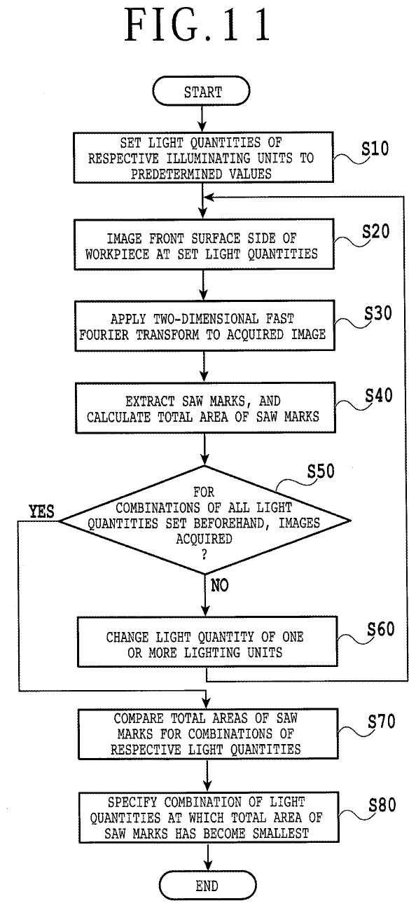

FIG. 11 is a flow diagram of a selection method of lighting conditions under which the total area of saw marks 19a becomes smallest in an image acquired by imaging the side of the front surface 11a. A setting step S10 to the specification step S80 are automatically performed by the controller 42. The controller 42 first sets the light quantities of the lighting units 14 to predetermined values (setting step S10). In the auxiliary storage device of the controller 42, predetermined values of the light quantities of the respective lighting units 14, the predetermined values being to be used first in the setting unit S10, are stored. However, these predetermined values may also be set by a worker through an input device (for example, a touch screen) disposed on the laser processing machine 32.

As the light quantities of the four lighting units 14 are adjustable from level 1 to level 5 as mentioned above, “the light quantity of the first lighting unit 14, the light quantity of the second lighting unit 14, the light quantity of the third lighting unit 14, the light quantity of the fourth lighting unit 14” are set, for example, to “1, 1, 1, 1.” If a DC power source is used, for example, the quantity of a current to be supplied from the DC power source is adjusted for the adjustment of each light quantity. If an alternate current power source is used, for example, on the other hand, the light quantity of each light source 16 is adjusted by a pulse width modulation control (PWM) method that modulates a pulse width, or a like method. After the setting step S10, the side of the front surface 11a of the workpiece 21 is imaged at the set light quantities by the microscope 2 through the back surface 11b (imaging step S20).

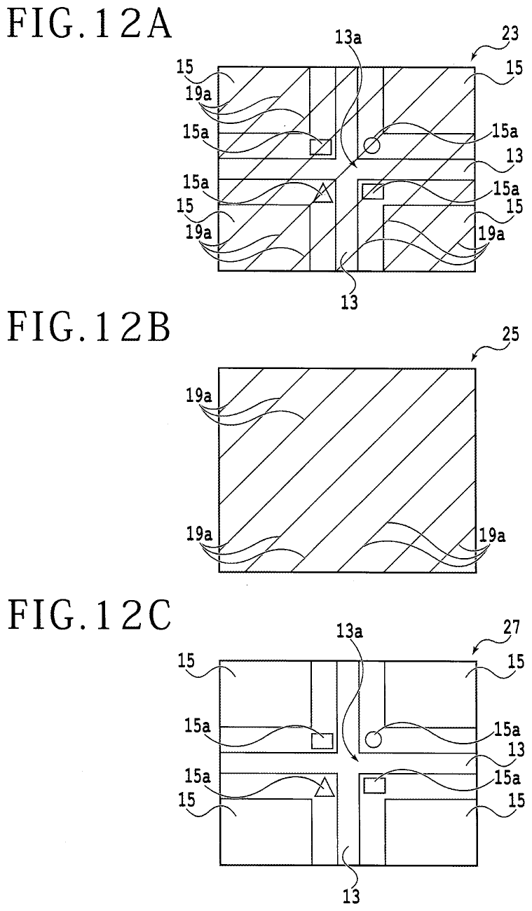

FIG. 12A is a schematic view of the first image 23 of the side of the front surface 11a including some of the saw marks 19a (hereinafter referred to as “the some saw marks 19a” or “the associated saw marks 19a”). The first image 23 includes the some saw marks 19a in addition to the predetermined patterns 15a to be used in the detection of a processing position. The controller 42 then applies image processing to the acquired first image 23. Described specifically, a two-dimensional FFT is applied to the first image 23 to create a transformed image (not depicted) having a pattern that indicates the distribution of the period of the some saw marks 19a included in the first image 23 (FFT step S30).

The first image 23 is an image on an X-Y plane where an X-axis direction serves as a horizontal axis and a Y-axis direction serves as a vertical axis, while the transformed image is, for example, an image where frequency components along an X-axis direction are plotted along a horizontal axis (U-axis), and frequency components along a Y-axis direction are plotted along a vertical axis (V-axis). It is to be noted that, in the transformed image, the associated saw marks 19a are represented by way of example as linear spectral lines passing through an origin on a U-V plane (not depicted).

On the basis of the first image 23, the controller 42 next extracts the associated saw marks 19a to create the second image 25 that does not include the predetermined patterns 15a, the scribe lines 13, the devices 15, and the like but includes the associated saw marks 19a, followed by a calculation of the total area of the associated saw marks 19a in the first image 23 (extraction and calculation step S40). Described specifically, after first applying image processing, such as masking other than the linear spectral lines corresponding to the associated saw marks 19a, to the transformed image, an inverse Fourier transform is applied to create the second image 25 with only the saw marks 19a extracted therein.

FIG. 12B is a schematic view of the second image 25 with only the saw marks 19a extracted therein. After acquiring the second image 25, black and white binarization processing is performed on the second image 25 using the predetermined pixel value as a threshold, the total pixel number, which constitute the associated saw marks 19a in the number of all pixels (overall pixel number) constituting the second image 25, is counted.

If, after the extraction and calculation step S40, first images 23 have not been acquired for combinations of all the light quantities set beforehand (“NO” in S50), the controller 42 changes the light quantity of one or more of the lighting units 14 (light quantity change step S60).

For example, the light quantities of the four lighting units 14 are set to “2, 1, 1, 1” by making an increment of only one level to the light quantity of the above-mentioned first lighting unit 14. The imaging step S20 to the extraction and calculation step S40 are then performed similarly. As another example, the light quantities of the four lighting units 14 are set to “0, 1, 1, 1” by making a decrement of only one level to the light quantity of the above-mentioned first lighting unit 14. The imaging step S20 to the extraction and calculation step S40 are then performed similarly.

For the combinations of all the light quantities set beforehand (specifically, 625 (=5⁴) combinations of “0,0, 0, 0” to “4,4, 4, 4”), the total pixel number of the associated saw marks 19a in the second image 25 is counted as described above. After the total pixel number has been counted for the combinations of all the light quantities (“YES” in S50), the counted total pixel numbers of the associated saw marks 19a are compared in magnitude (comparison step S70). The controller 70 then specifies the combination of light quantities at which the total pixel number of the associated saw marks 19a has become smallest (specification step S80). In the manner as described above, the lighting conditions under which the total area of the associated saw marks 19a becomes smallest is selected.

By creating the second images 25 from the individual first images 23 based on the first images 23 acquired, respectively, by imaging the front surface 11a under the different sets of lighting conditions changed through the stepwise adjustments of the light quantities of the respective lighting units 14, and calculating the total areas of the associated saw marks 19a in the respective second images 25, the controller 42 therefore specifies the lighting conditions under which the total area of the associated saw marks 19a has become smallest.

It is to be noted that, as mentioned above, the light beam (which has the second component D2) from the lighting unit 14 located at each position D is prone to reflection on the side of the back surface 11b compared with the light beam (which has the first component C1) from the lighting unit 14 located at each position C. Under the lighting conditions so selected, the light quantity of the lighting unit 14 located at each position D is therefore smaller compared with the light quantity of the lighting unit 14 located at each position C. The light quantity of the lighting unit 14 located at each position D is set, for example, to level 1 (light quantity: zero).

When laser processing is applied to the workpiece 21 by the laser processing machine 32, the workpiece 21 is processed by controlling the laser beam irradiation unit 38 on the basis of the first image 23 that includes the predetermined patterns 15a and has been captured using the above-mentioned selected lighting conditions. Described specifically, the workpiece 21, which is held at the side of the front surface 11a under suction on the holding surface 34a such that the back surface 11b is exposed, is first imaged by the microscope 2 using the above-mentioned selected lighting conditions.

This can image the side of the front surface 11a under conditions under which the saw marks 19a on the side of the back surface 11b are relatively hard to be reflected in. It is to be noted that the controller 42 may acquire the image of the side of the front surface 11a, which corresponds to the above-mentioned selected lighting conditions, by image processing without newly imaging the side of the front surface 11a.

FIG. 12C is a schematic view of an image (specifically, third image 27) of the side of the front surface 11a, which corresponds to the lighting conditions that are selected through the setting step S10 to the specification step S80 and that are relatively hard to allow the saw marks 19a to be reflected in. It is to be noted that the selection of the lighting conditions (in other words, S10 to S80) is performed every time the imaging position of the microscope 2 is changed. When the detection of the processing position is performed using the predetermined patterns 15a, the third image 27 is used. As the saw marks 19a are relatively suppressed from being reflected in the third image 27, it is facilitated to correctly recognize the predetermined patterns 15a in image processing.

After the detection of the processing position, the angle of rotation of the holding table 34 is adjusted to bring the associated single scribe line into substantially parallel to the X-axis direction. Laser processing is then applied to the workpiece 21 by positioning the focal point of the laser beam L on the back surface 11b or in the interior of the workpiece 21 and relatively moving the holding table 34 and the focal point along the X-axis direction.

The laser processing machine according to this embodiment has the above-mentioned microscope 2. Compared with the case of coaxial lighting, it is therefore possible to reduce the light quantity of light reflected on the side of the back surface 11b and entering the objective lens 4 and to increase the light quantity of light scattered on the front surface 11a or in the interior of the workpiece 21 and entering the objective lens 4. As the effects of the reflected light from the side of the back surface 11b can be reduced as described above, the noise to be caused by the reflected light from the side of the back surface 11b can be reduced. Compared with the oblique lighting of the related art that irradiates parallel light beams, it is also possible to increase the quantities of the light beams that reach the front surface 11a or interior of the workpiece 21.

### (Cutting Machine)

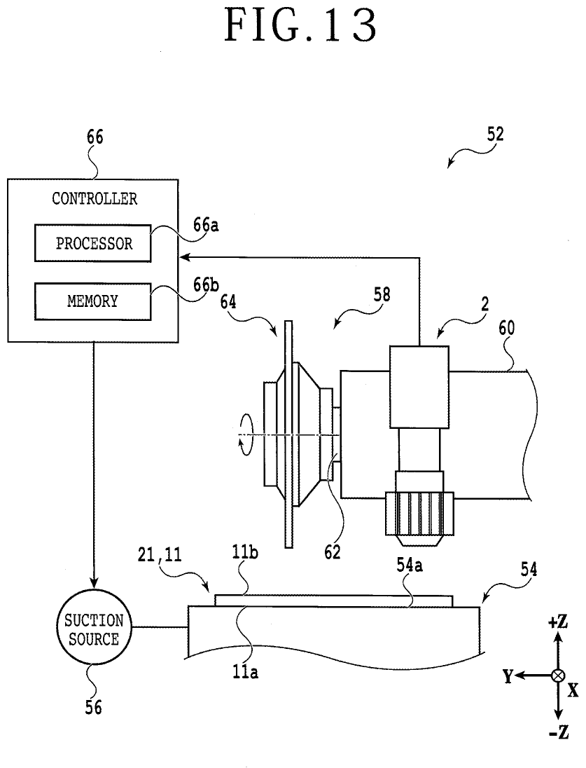

As a processing machine according to a second embodiment of the third aspect of the present invention, the cutting machine 52 with the microscope 2 mounted thereon will hereinafter be described with reference to FIG. 13. FIG. 13 is a side view schematically depicting the cutting machine 52. It is to be noted that, in FIG. 13, some elements of the cutting machine 52 are illustrated as functional blocks. The cutting machine 52 has a disk-shaped holding table 54.

As the holding table 54 is substantially the same as the above-mentioned holding table 34, its detailed description is omitted. A suction source 56 such as a vacuum pump is connected to the holding table 54. On a holding surface 54a of the holding table 54, the workpiece 21 is held at the side of the front surface 11a under suction such that the side of the back surface 11b is exposed. The holding table 54 is constructed to be movable along an X-axis direction (processing feed direction) by an X-axis direction moving mechanism (not depicted) of a ball screw type.

Above the holding table 54, a cutting unit (processing unit) 58 is disposed. The cutting unit 58 has a square cylindrical spindle housing 60 having a longitudinal portion arranged along a Y-axis direction. In the spindle housing 60, a cylindrical spindle 62 is accommodated, in part, to be rotatable. In a vicinity of a proximal end portion of the spindle 62, a rotary drive source (not depicted) such as a servomotor is disposed. The spindle 62 projects at a distal end portion thereof from the spindle housing 60, and a cutting blade 64 with an annular cutting edge is fitted on the distal end portion.

In a side way of the spindle housing 60, the above-mentioned microscope 2 is fixed via an undepicted arm extending in the X-axis direction. The microscope 2 is arranged such that the optical axis 4a of the objective lens 4 extends along a Z-axis direction. The spindle housing 60 is constructed to be movable along the Z-axis direction (height direction) by a Z-axis direction moving mechanism (not depicted) of a ball screw type. For example, the position of a cut-in depth of the cutting blade 64 and the focal point of the objective lens 4 of the microscope 2 are adjusted by the Z-axis direction moving mechanism.

The Z-axis moving mechanism is constructed to be movable along the Y-axis direction (indexing feed direction) by a Y-axis direction moving mechanism of a ball screw type. The position in the Y-axis direction of the cutting blade 64 is adjusted by the Y-axis direction moving mechanism. Operations of the microscope 2, the holding table 34 (in other words, the suction source 56, the X-axis direction moving mechanism, and so on), the cutting unit 58, the Y-axis direction moving mechanism, the Z-axis direction moving mechanism, and the like are controlled by a controller 66.

The controller 66 is constituted by a computer, which includes, for example, a processor 66a typified by a CPU, and a memory 66b. The memory 66b has a main storage device such as a DRAM, and an auxiliary storage device such as a flash memory, a hard-disk drive, or a solid-state drive. In the auxiliary storage device, software including predetermined programs is stored. Functions of the controller 66 are realized by operating the processor 66a and the like in accordance with the software.

Similar to the controller 42, the controller 66 also selects, through the setting step S10 to the specification step S80, lighting conditions under which the total area of the associated saw marks 19a becomes smallest. In the controller 66, programs that execute the setting step S10 to the specification step S80 are also stored as in the controller 42.

Under the lighting conditions selected through the setting step S10 to the specification step S80, the controller 66 controls the cutting unit 58 on the basis of the image of the workpiece 21 as captured by the microscope 2, thereby cutting the workpiece 21 along the associated scribe line 13 (in other words, applying processing to the workpiece 21). It is to be noted that, if the positional relations between the lighting units 14 and the associated saw marks 19a are known beforehand, the controller 66 may set the lighting conditions so as to make the quantity of light beams, which have the second component D2, from the lighting units 14 (position D), smaller than the quantity of light beams, which have the first component C1, from the lighting units 14 (position C).

The cutting machine 52 as the processing machine according to the second embodiment of the third aspect also has the above-mentioned microscope 2. Compared with the case of coaxial lighting, it is therefore possible to reduce the light quantity of light reflected on the side of the back surface 11b and entering the objective lens 4 and to increase the light quantity of light scattered on the front surface 11a or in the interior of the workpiece 21 and entering the objective lens 4. As the effects of the reflected light from the side of the back surface 11b can be reduced as described above, the noise to be caused by the reflected light from the side of the back surface 11b can be reduced. Compared with the oblique lighting of the related art that irradiates parallel light beams, it is also possible to increase the quantities of the light beams that reach the front surface 11a or interior of the workpiece 21.

It is to be noted that the constructions, the method, and the like according to the above-mentioned embodiments can be practiced with changes or modifications made as appropriate to such extent as not departing from the scope of the object of the present invention. The number of the lighting units 14 in the microscope 2 is not limited to four. The microscope 2 may have two, three, five, or more lighting unis 14. Further, if modified regions and cracks are formed along the scribe lines 13 in the interior of the workpiece 21, these modified regions and cracks can also be imaged using the microscope 2 disposed in the laser processing machine 32.

The present invention is not limited to the details of the above described preferred embodiments. The scope of the invention is defined by the appended claims and all changes and modifications as fall within the equivalence of the scope of the claims are therefore to be embraced by the invention.

What is claimed is:

1. An observation method for irradiating one side of an object, the object having a plate shape, the one side, and the other side located on an opposite side to the one side, with a light beam, and observing the other side of the object or an interior of the object, comprising:
a holding step of holding the object at the other side on a holding surface of a holding table; and
a detection step of, after the holding step, irradiating the object with the light beam from a lighting unit that is capable of applying the light beam with a wavelength having transmissivity for the object, with a focal point of the light beam being positioned at a predetermined position on the other side or in the interior, and detecting reflected light from the object by an imaging unit including an objective lens having an optical axis inclined obliquely to an optical axis of a condenser lens of the lighting unit.

2. The observation method according to claim 1, wherein, in the detection step, at least one additional lighting unit that has a condenser lens having an optical axis inclined obliquely to the optical axis of the objective lens and is capable of irradiating the object with a light beam with the wavelength having transmissivity for the object is used, the respective lighting units are arranged at a plurality of positions different from one another along a circumference of a circle centering around the optical axis of the objective lens, the object is irradiated with the light beams from the respective lighting units with the focal point of the light beam from the lighting unit and a focal point of the light beam from the additional lighting unit positioned at the predetermined position on the other side or in the interior, and reflected light from the object are detected by the imaging unit.

3. A microscope for irradiating one side of an object, the object having a plate shape, the one side, and the other side located on an opposite side to the one side, with a light beam, and observing the other side of the object or an interior of the object, comprising:
a lighting unit that has a light source capable of emitting the light beam with a predetermined wavelength to allow the light beam to transmit through the object, and a condenser lens capable of focusing the light beam from the light source at a predetermined position on the other side or in the interior of the object, and irradiates the object with the light beam; and
an imaging unit that has an objective lens capable of allowing passage therethrough of reflected light from the object irradiated with the light beam, and an imaging sensor capable of receiving the reflected light through the objective lens, wherein
the condenser lens has an optical axis inclined obliquely to an optical axis of the objective lens.

4. The microscope according to claim 3, wherein, in a first direction from the objective lens, as a start point, on the optical axis of the objective lens to a region, as an end point, where the optical axis of the objective lens and the optical axis of the condenser lens come closest to each other, the condenser lens of the lighting unit is arranged on a side closer to the end point than the objective lens.

5. The microscope according to claim 3, further comprising:
at least one additional lighting unit having a light source capable of emitting a light beam with the predetermined wavelength, and a condenser lens capable of focusing the light beam from the light source at the predetermined position on the other side or in the interior of the object and having an optical axis inclined obliquely to the optical axis of the objective lens, wherein
the respective lighting units are arranged at a plurality of positions different from one another along a circumference of a circle centering around the optical axis of the objective lens, and the optical axes of the condenser lenses in the respective lighting units are inclined obliquely to the optical axis of the objective lens.

6. A processing machine for processing a workpiece having a plate shape, comprising:
a holding table that has a holding surface capable of holding the workpiece, the workpiece having one side and the other side located on an opposite side to the one side, at the other side with the one side of the workpiece exposed;
a processing unit that is able to apply processing to the workpiece held on the holding table;
a microscope that is able to observe the other side of the workpiece or an interior of the workpiece; and
a controller that has a memory and a processor and is configured to control operations of the holding table, the processing unit, and the microscope, wherein
the microscope has
a lighting unit that has a light source capable of emitting a light beam with a predetermined wavelength to allow the light beam to transmit through the workpiece, and a condenser lens capable of focusing the light beam from the light source at a predetermined position on the other side or in the interior of the object, and irradiates the workpiece with the light beam, and
an imaging unit that has an objective lens capable of allowing passage therethrough of reflected light from the object irradiated with the light beam, and an imaging sensor capable of receiving the reflected light through the objective lens,
the condenser lens has an optical axis inclined obliquely to an optical axis of the objective lens, and
the controller applies the processing to the workpiece by controlling the processing unit on a basis of an image of the workpiece as captured by the microscope.

7. The processing machine according to claim 6, wherein, in a first direction from the objective lens, as a start point, on the optical axis of the objective lens to a region, as an end point, where the optical axis of the objective lens and the optical axis of the condenser lens come closest to each other, the condenser lens of the lighting unit is arranged on a side closer to the end point than the objective lens in the microscope.

8. The processing machine according to claim 6, wherein
the microscope further includes at least one additional lighting unit having a light source capable of emitting a light beam with the predetermined wavelength, and a condenser lens capable of focusing the light beam from the light source at the predetermined position on the other side or in the interior of the object and having an optical axis inclined obliquely to the optical axis of the objective lens, and
the respective lighting units are arranged at a plurality of positions different from one another along a circumference of a circle centering around the optical axis of the objective lens, and the optical axes of the condenser lenses in the respective lighting units are inclined obliquely to the optical axis of the objective lens.

9. The processing machine according to claim 6, wherein,
if predetermined patterns usable when a detection of a processing position of the workpiece is performed are formed on the other side of the workpiece,
the controller applies the processing to the workpiece by controlling the processing unit on a basis of an image of the other side of the workpiece, the image including the predetermined patterns, as captured by imaging the other side with the microscope.

10. The processing machine according to claim 8, wherein,
if saw marks caused by grinding processing are formed on the one side of the workpiece,
the lighting units include a plurality of first lighting units capable of applying light beams having a first component along a direction of some of the saw marks, the some saw marks being located in an imaging range of the imaging unit, and a plurality of second lighting units capable of applying light beams having a second component along a direction orthogonal to the first component as seen in plan view, and
the controller reduces light quantities of the second lighting units compared with light quantities of the first lighting units by adjusting the light quantities of the first lighting units and the light quantities of the second lighting units.

11. The processing machine according to claim 8, wherein,
if saw marks caused by grinding processing are formed on the one side of the workpiece,
the controller creates, on a basis of a plurality of first images acquired, respectively, by imaging the other surface under a plurality of different sets of lighting conditions changed through stepwise adjustments of the light quantity of the respective lighting units and each containing predetermined patterns formed on the other side of the workpiece and some of the saw marks, a plurality of second images each containing the some saw marks without the predetermined patterns, calculates a total area of the some saw marks in each second image, and specifies the lighting conditions under which the total area of the some saw marks has become smallest.

12. The processing machine according to claim 6, wherein the processing unit includes a laser beam irradiation unit having a laser oscillator, or a cutting unit having a spindle and a cutting blade fitted on a distal end portion of the spindle.
